(19) United States
(12) Patent Application Publication
(10) Pub. No.: US 2011/0075489 A1
(43) Pub. Date: Mar. 31, 2011

(54) NON-VOLATILE SEMICONDUCTOR MEMORY DEVICE

(75) Inventors: Takashi YAMANE, Kanagawa-ken (JP); Atsuhiro Sato, Tokyo (JP)

(73) Assignee: KABUSHIKI KAISHA TOSHIBA, Tokyo (JP)

(21) Appl. No.: 12/718,428

(22) Filed: Mar. 5, 2010

(30) Foreign Application Priority Data
Sep. 30, 2009 (JP) 2009-228920

(51) Int. Cl. G11C 16/06; G11C 16/04

(52) U.S. Cl. 365/185.22; 365/185.18

(57) ABSTRACT

Two or more writing prohibition voltages are applied to bit lines connected to memory cell transistors corresponding to the writing voltage of word lines in a writing operation to write data in the memory cell transistors, while increasing the writing voltage of the word line in a stepwise. Two or more selection gate line voltages, corresponding to the writing prohibition voltages applied to the bit lines, are applied to the gates of selection gate transistors.

### CROSS-REFERENCE TO RELATED APPLICATION

This application is based upon and claims the benefit of priority from prior Japanese Patent Application No. 2009-228920, filed Sep. 30, 2009, the entire contents of which are incorporated herein by reference.

### BACKGROUND OF THE INVENTION

1. Field of the Invention

The invention relates to a non-volatile semiconductor memory device, and more particularly, to a method for writing data to a NAND-type flash memory.

2. Description of the Related Art

A NAND-type flash memory, i.e, non-volatile semiconductor memory device, is widely used as a large-capacity storage medium. A memory cell transistor in an NAND-type flash memory has a stacked gate structure in which a charge accumulation layer (floating gate) and a control gate are stacked on a semiconductor substrate via an insulating film. A plurality of memory cell transistors are connected in series in such a manner that the adjacent memory cell transistors share the source or the drain of each other, and selection gate transistors are arranged on both ends of the plurality of memory cell transistors connected in series, to structure a NAND string.

A memory cell transistor uses the state of charge accumulation of the floating gate to store data in a non-volatile manner. More specifically, the memory cell transistor stores two-level data, in which, for example, data “0” is represented by a state that electrons have been injected to the floating gate from the channel, i.e., a state that a threshold voltage Vth is high, and data “1” is represented by a state that electrons in the floating gate have been discharged to the channel, i.e., a state that the threshold voltage Vth is low. A multi-valued memory method such as four-level memory is achieved by having distribution control of the threshold voltage broken into many segments.

When data are written, data in a memory cell transistor in an NAND cell block are collectively erased in advance. Such an erase-ing operation is performed by causing the voltage of all control gate lines (word lines) in the selected NAND cell block to be Vss(=0V) and giving a boosted positive voltage Vera (erase voltage) to a P-type well in the memory cell array so as to discharge electrons in the floating gate to the channel. As a result of the operation, all the data in the memory cell transistor in the NAND cell block attain state “1” (erased state).

After the above collective data erase, data are collectively written into a plurality of memory cell transistors along the selected gate line (usually referred to as one page) in order from the source side. When a boosted positive writing voltage Vpgm is given to the selected word line, data are written in the following manner. In a case of data “0”, electrons are injected from the channel into the floating gate (so-called “0” writing), and in a case of data “1”, electron injection is prohibited (so called writing prohibition or “1” writing).

In the above-described collective data writing operation to the memory cell transistor along the control gate line, it is necessary to control the channel potential of the memory cell transistor according to data. For example, when “0” is written, the channel potential is kept low, and when a writing voltage is applied to the control gate, a strong electric field is applied to the gate insulating film between the channel and the floating gate. When “1” is written, the channel potential is boosted, so that electron injection into the floating gate is prohibited.

There are various methods for controlling the channel potential for the above data writing operation. Japanese Patent Application Laid-Open No. 2002-260390 discloses a self-boost method for increasing the channel potential by a capacitive coupling with the control gate while the channel is caused to be in the floating state when data “1” are written. More specifically, in the method, before a writing voltage is applied to the control gate line, voltage is applied according to data “0” and “1” in the following manner. In a case of data “0”, Vss (=0 V) is applied to a bit line, and in a case of data “1”, Vdd (power supply voltage, for example 3 V) is applied to the bit line. At the moment, the source line side selection gate transistor is put in an OFF state in any case. Hereinafter, the voltage applied to the bit line in order to write “1” is referred to as “writing prohibition voltage”.

In a case of data “0”, the bit line side selection gate transistor is ON state, Vss is transferred to the channel of the NAND string. At this moment, the channel potential is kept at Vss, and therefore, a strong electric field is applied between the channel and the floating gate, and electrons are injected from the channel to the floating gate.

In a case of data “1”, first the channel of the NAND string is pre-charged to a potential (Vdd+α−Vsth), i.e., a voltage applied to the gate of the selection gate transistor (for example, Vdd+α) decreased by a threshold voltage of the selection gate transistor (Vsth). According, the selection gate transistor attains OFF state, and the channel attains the floating state. At the moment, the channel potential increases by a capacitive coupling between the writing voltage Vpgm applied to the selected control gate and an intermediate voltage Vpass applied to a non-selected control gate. Since the electric field between the channel and the floating gate is small, electrons are not injected from the channel to the floating gate.

However, in the above-mentioned self-boosting method described in the Laid-Open Publication No. 2002-260390, when “1” is written, reverse bias is applied to a junction between the bit line contact and the P-type well, and junction leakage current is generated.

### BRIEF SUMMARY OF THE INVENTION

According to one aspect of the present invention, there is provided a non-volatile semiconductor memory device including: a semiconductor substrate; a plurality of element regions formed on the substrate in a column direction and separated by element isolation regions arranged between adjacent element regions, respectively; a plurality of memory cell transistors connected in series on the plurality of element regions, respective memory cell transistors including diffusion regions, a gate insulating layer, a charge accumulation layer and a control gate; a selection gate transistor formed on the element regions, connected to one terminal of the plurality of memory cell transistors arranged in series and having diffusion regions, a gate insulating layer and a gate; bit lines formed extending in the column direction and connected to the diffusion regions of the selection gate transistors on the opposite side of the memory cell transistors; word lines extending in a row direction to respectively connect adjacent control gates of the memory cell transistors; a selection gate line arranged in parallel with the word lines to respectively connect gates of adjacent selection gate transistors; and wherein two or more values of writing prohibition voltages are applied to the bit lines corresponding to a writing voltage of the word line, during a writing operation to write data in the memory cell transistor while the writing voltage of the word line is increased in a stepwise, and two or more values of selection gate line voltages, corresponding to the writing prohibition voltages applied to the bit lines, are applied to the gates of the selection gate transistors.

### BRIEF DESCRIPTION OF THE DRAWINGS

The accompanying drawings, which are incorporated in and constitute a part of the specification, illustrate embodiments of the invention, and together with the general description given above and the detailed description of the embodiments given below, serve to explain the principles of the invention.

FIG. 1 is a block diagram showing a NAND-type flash memory according to the first embodiment of the invention,

FIG. 2 is a circuit diagram showing an equivalent circuit of a memory cell of the NAND-type flash memory according to the first embodiment of the invention,

FIG. 3 is a plan view showing a NAND string of the NAND-type flash memory according to the first embodiment of the invention,

FIG. 4 is a cross sectional diagram showing the NAND string of the NAND-type flash memory according to the first embodiment of the invention, taken along the line A to A′ of FIG. 3 and seen from the direction indicated by the arrow,

FIG. 5 is a cross sectional diagram showing the NAND string of the NAND-type flash memory according to the first embodiment of the invention, taken along the line B to B′ of FIG. 3 and seen from the direction indicated by the arrow,

FIG. 6 is a figure illustrating a channel potential during writing operation of “1” in the NAND-type flash memory according to the first embodiment of the invention,

FIG. 7 is a figure showing a bit line potential and a writing word line potential during writing operation of “1” in the NAND-type flash memory according to the first embodiment of the invention,

FIG. 8 is a figure showing a bit line potential and a writing word line potential during writing operation of “1” in the NAND-type flash memory according to a second embodiment of the invention, and

FIG. 9 is a figure showing verification operation performed by the NAND-type flash memory according to the second embodiment of the invention.

### DETAILED DESCRIPTION OF THE INVENTION

A non-volatile semiconductor memory device according to an exemplary embodiment of the present invention will now be described with reference to the accompanying drawings wherein the same or like reference numerals designate the same or corresponding parts throughout the several views.

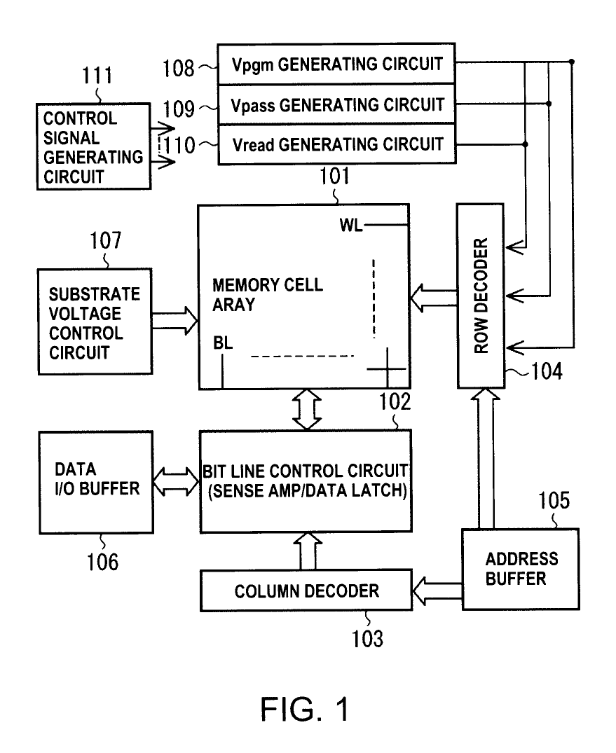

FIG. 1 is a block diagram of a non-volatile semiconductor memory device (for example, NAND-type flash memory) according to an embodiment of the invention. The NAND-type flash memory according to the present embodiment includes a memory cell array 101, a bit line control circuit 102 (sense amplifier/data latch), a column decoder 103, a row decoder 104, an address buffer 105, a data input/output buffer 106, a substrate voltage control circuit 107, a Vpgm generating circuit 108, a Vpass generating circuit 109, a Vread generating circuit 110, and a control signal generating circuit 111.

As described above, the memory cell array 101 is structured by arranging the NAND string including non-volatile memory cells connected in series.

A sense amplifier/data latch (bit line control circuit) 102 is arranged to sense the bit line data of the memory cell array 101 or maintain writing data. The circuit performs bit line potential control in verification reading after data writing and rewriting to an insufficiently written memory cell, and is mainly constituted by, for example, a CMOS flip flop.

The sense amplifier/data latch 102 is connected to the data input/output buffer 106. A connection between the sense amplifier/data latch 102 and the data input/output buffer 106 is controlled by an output from the column decoder 103 that receives an address signal from the address buffer 105.

The row decoder 104 is arranged to select a memory cell in the memory cell array 101. More specifically, the row decoder 104 is arranged to control a control gate and a selection gate.

The writing voltage (Vpgm) generating circuit 108 is arranged to generate the writing voltage Vpgm boosted from the power supply voltage, when data are written into a selected memory cell of the memory cell array 101. In addition to the Vpgm generating circuit 108, the writing intermediate voltage (Vpass) generating circuit 109 and the reading intermediate voltage (Vread) generating circuit 110 are arranged. The writing intermediate voltage (Vpass) generating circuit 109 generates a writing intermediate voltage Vpass given to a non-selected memory cell during data writing operation. The reading intermediate voltage (Vread) generating circuit 110 generates a reading intermediate voltage Vread given to a non-selected memory cell during data reading operation (including verification reading operation).

The writing intermediate voltage Vpass and the reading intermediate voltage Vread are lower than the writing voltage Vpgm but are voltages boosted from a power supply voltage Vcc. The control signal generating circuit 111 controls, e.g., writing operation, erasing operation, reading operation, writing verification operation, excessive writing verification operation, data erasing operation for a unit of data latch, and the writing operation for varying and setting an initial voltage of writing operation and a voltage pulse equivalent to step-up.

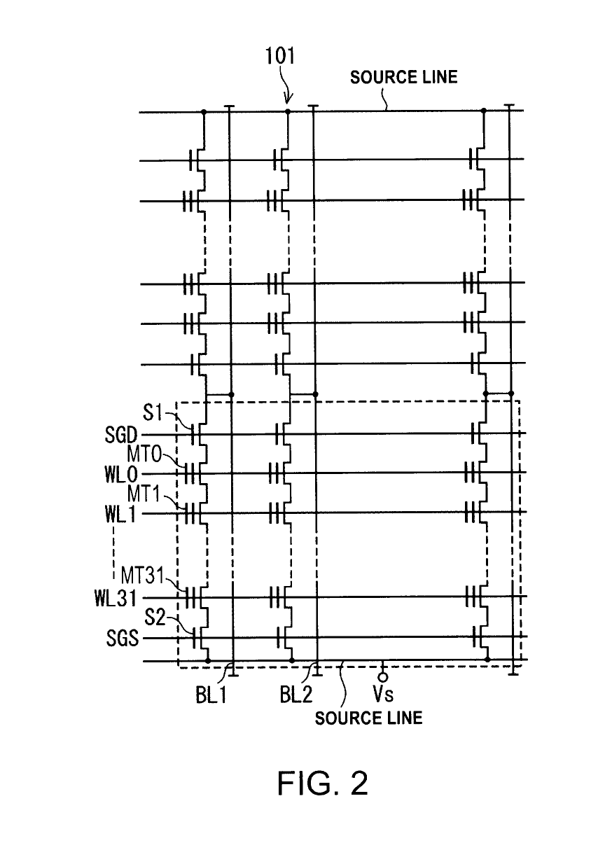

FIG. 2 is an equivalent circuit of the memory cell array 101. A plurality of memory cell transistors (MT) are connected in series in the column direction, and selection transistors (S1, S2) are connected to both ends thereof, so that a NAND string is structured. Between a plurality of NAND strings arranged in the row direction, the memory cell transistors MO to M31 are commonly connected by word lines (WL0, WL1, . . . , WL31). Between the plurality of NAND strings arranged in the row direction, the selection transistors (S1, S2) are commonly connected by a drain side selection gate word line SGD and a source side selection gate word line SGS, in the same manner as the memory cell transistor M0 to M31. One end of each of the NAND strings is connected to the bit lines (BL1, BL2), and the other end is connected to the source line.

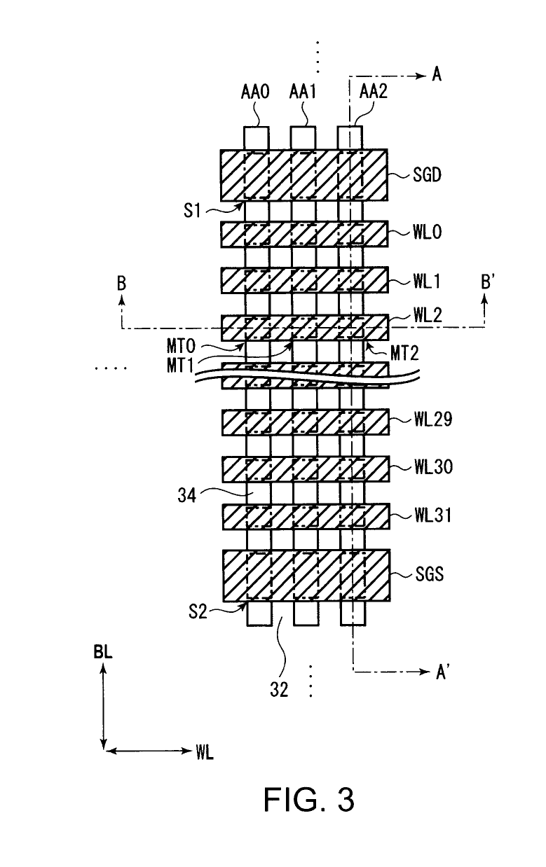

FIG. 3 is a plan view showing the NAND string constituting the memory cell array 101. As shown in FIG. 3, a plurality of element regions AA0 to AA2 are arranged on a principal surface of a semiconductor substrate 31. These element regions AA0 to AA2 are formed in a belt shape in a predetermined direction, i.e., in the vertical direction of FIG. 3, and are arranged spaced apart from each other.

These element regions AA0 to AA21 are insulated and spaced apart from each other by an element isolation region 32. The element regions AA0 to AA2 are formed with a plurality of diffusion regions 34 serving as source/drain of the memory cell transistors MT. The plurality of diffusion regions 34 are formed spaced apart from each other by the word lines WL of the memory cell transistors MT. The adjacent diffusion regions 34 are shared, so that the plurality of memory cell transistors MT are connected in series to form a NAND string.

On the element regions AA0 to AA2 and the element separation regions 32, the word lines WL of the plurality of memory cell transistors MT are arranged in the row direction in FIG. 3, and the selection gate lines SGS/SGD of the selection gate transistor S1/S2 are arranged in parallel with the word lines WL.

Under each of the word lines WL intersecting with each of the element regions AA0 to AA2, a channel of a memory cell transistor MT is formed. Under the selection gate lines SGS/SGD intersecting with each of the element regions AA0 to AA2, channels of the selection transistors S1, S2 are formed respectively. The diffusion regions S or D of the selection transistors S1, S2 are connected to the bit line contact and the source line contact, respectively.

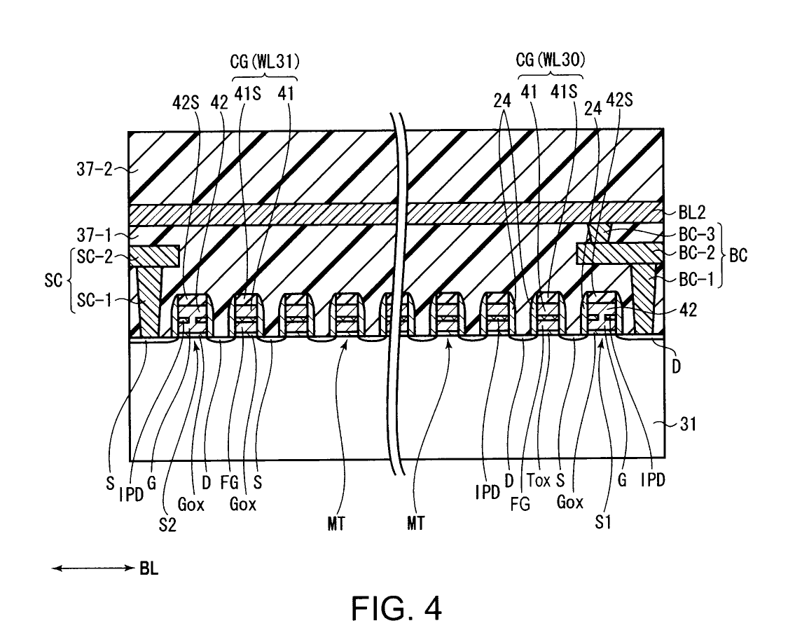

FIG. 4 is a cross sectional diagram taken along line A to A′ of FIG. 3. As shown in FIG. 4, each of the memory cells has a stacked structure including a tunnel insulating film Tox arranged on P-type well (not shown) formed in the semiconductor substrate, a floating gate FG arranged on the tunnel insulating film Tox, an inter-gate insulating film IPD arranged on the floating gate FG, a control gate CG 41 arranged on the inter-gate insulating film IPD, and a silicide layer 41S arranged on the control gate CG 41. Each of the memory cells constitutes a memory cell transistor MT whose threshold voltage changes according to accumulation of charge in the floating gate FG. The floating gate FG of each of the memory cell transistors MT is electrically separated. The control gate CG is connected to the word lines WL0 to WL31, and is commonly, electrically connected at the memory cell transistors in the word line direction (row line direction).

Each of the memory cell transistors MT includes a spacer 24 arranged along the sidewall of the above stacked structure and a source S or a drain D arranged in the P well that is arranged to sandwich the above stacked structure.

Each of the selection gate transistors S1, S2 includes a gate insulating film Gox, an inter-gate insulating film IPD, a gate electrode G, and a silicide layer 42S. The inter-gate insulating film IPD is arranged to electrically connect the gate electrodes G separated into upper and lower layers. A silicide layer 42S is arranged on the gate electrode G.

Further, each of the selection gate transistors S1, S2 includes the spacer 24 arranged along the sidewall of the gate electrode G and a source S or a drain D arranged in the P well that is arranged to sandwich the gate electrode G.

The gate electrodes G of the selection gate transistor S1, S2 are connected to the selection gate lines SGD, SGS, respectively, so that the selection gate transistor S1, S2 select a NAND string along the bit line BL direction and connect to the bit line BL.

The source S of the selection gate transistor S2 is connected to the source line via source line contacts SC-1, SC-2 in an inter-layer insulating film 37-1.

A bit line BL2 is arranged in the inter-layer insulating films 37-1, 37-2. The bit line BL2 is electrically connected to the drain D of the selection gate transistor S1 via bit line contacts BC1 to BC3 in the inter-layer insulating film 37-1.

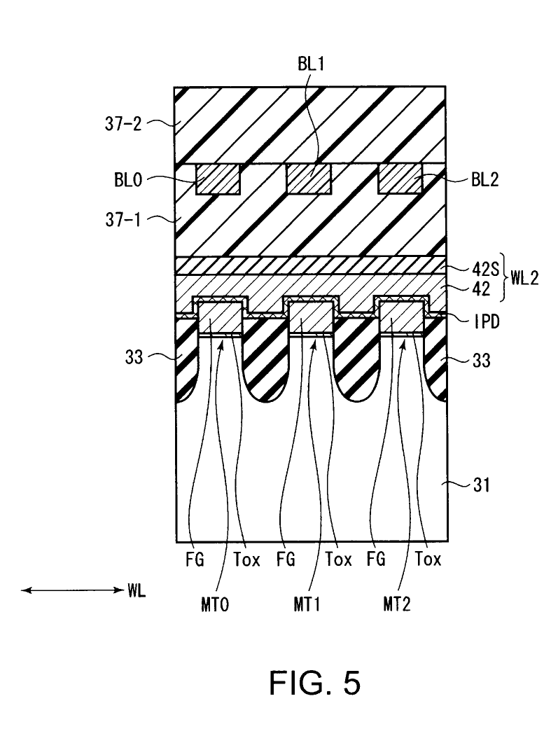

FIG. 5 is a cross sectional diagram taken along line B-B′ of FIG. 3. As shown in FIG. 5, in an element region delaminated by an element separation insulating film 33, the memory cell transistors MT0 to MT2 are arranged at intersecting positions between the word line WL2 and the bit lines BL to BL2.

At least one or more selection gate lines SGS and SGD are necessary in each of NAND strings. The number of the memory cell transistors MT in the NAND string is not limited to the number described in the present embodiment. The number of memory cells in the NAND string may be two or more. In view of address decoding, it is preferable that the number of memory cells be 2n (n is a positive integer) or 2ⁿ plus about one to 4 dummy cells.

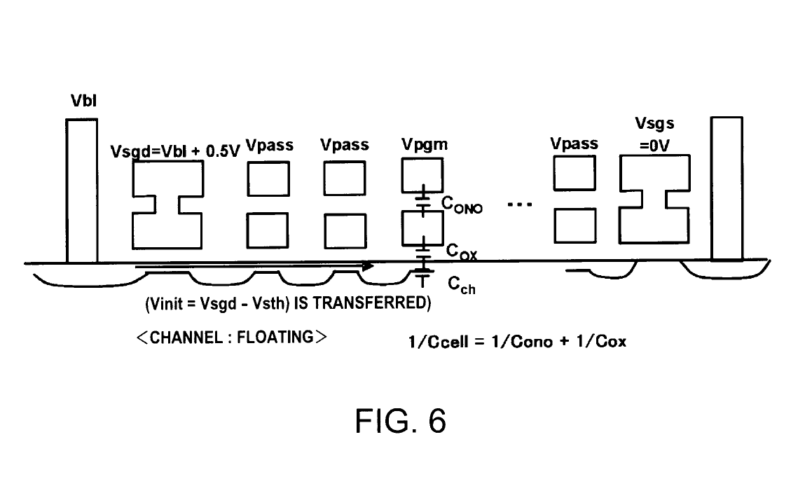

Subsequently, a channel potential Vch during writing operation of “1” in the non-volatile semiconductor memory device according to the embodiment of the invention will be described with reference to FIG. 6.

The ultimate channel potential Vch is a summation of an initial transfer potential Vinit transferred from the bit line to the channel and a potential Vbst boosted by a capacitive coupling from the potential Vpass of the non-selected word line.

Vch=Vinit+Vbst

First, an initial transfer potential Vinit is obtained. It is assumed that the bit line potential is Vbl, and the gate potential Vsgd of the bit line side selection gate transistor S1 is

Vsgd=Vbl+0.5V.

In the example, the threshold voltage Vsth of the selection gate transistor S1 is assumed to be larger than 0.5 V. Accordingly, the bit line potential Vbl is transferred to the channel until a difference between the gate potential Vsgd and the initial transfer potential Vinit becomes the same as the threshold voltage Vsth. Thereafter, the bit line selection gate transistor S1 turns off (the channel is floating), and therefore the following expression holds.

Vinit=Vsgd·Vsth.

Subsequently, the boosted potential Vbst is derived. Where the capacitance of the channel is Cch and the capacitance of the cell is Ccell, the potential Vbst boosted by the capacitive coupling is as follows.

Vbst=Vpass×Ccell/(Ccell+Cch)

For the sake of simplicity, it is assumed that Cch is nearly eqall to Ccell. As a result the, below expression holds.

Vch=Vinit+Vpass×0.5 (Expression (1))

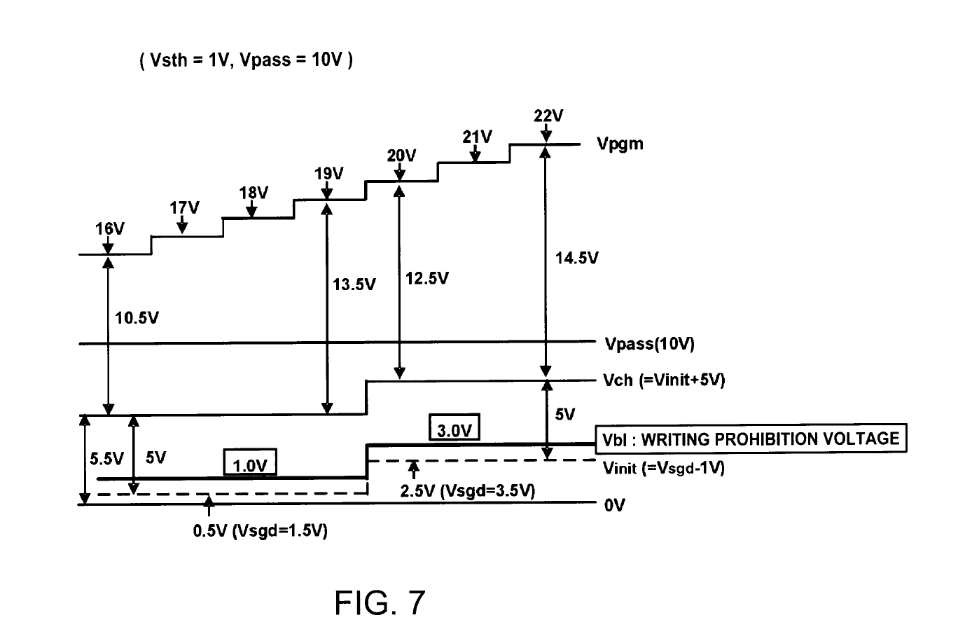

FIG. 7 shows a word line application voltage, a bit line application voltage, and a channel potential during writing operation of “1” in the non-volatile memory device (NAND flash memory) according to the first embodiment of the invention. A step-up writing operation is performed on the selected word line such that, for example, the writing voltage Vpgm is increased by 1 V step from 16 V. A constant voltage of the non-selected word line potential Vpass (10 V) is applied to the non-selected word line. A writing prohibition voltage Vbl (1.0 V) is applied to the bit line, and the gate potential Vsgd (1.5 V) is applied to the gate of the bit line side selection gate transistor S1. It should be noted that a conventional writing prohibition voltage Vbl is about the power supply voltage Vdd (3 V). When the writing prohibition voltage Vbl is set to be less than the conventional writing prohibition voltage, the reverse bias applied between the bit line contact BC and the semiconductor substrate (P-type well) 31 becomes smaller. Therefore, the junction leakage current at the bit line contact BC area decreases, and the overall power consumption of the chip decreases.

When the writing prohibition voltage Vbl is set to be 1 V and the gate potential Vsgd is set to be 1.5 V, the channel potential Vch decreases, and there is a possibility of false writing occurring due to electron injection from the channel to the floating gate. However, when the threshold voltage Vsth is set to be 1V and the non-selected word line potential Vpass is set to be 10 V, the channel potential Vch attains 5.5 V on the basis of the expression (1).

The potential difference between the channel and the control gate is 10.5 V (where Vpgm is 16 V) to 13.5 V (where Vpgm is 19 V), which is less than the potential difference 16 V at the start of writing operation. Therefore, false writing does not occur.

When the writing voltage Vpgm is stepped up, the writing prohibition voltage Vbl and the gate voltage Vsgd are also stepped up. In the example, when the writing voltage Vpgm is 20 V, the writing prohibition voltage Vbl is set to be 3 V, and the gate voltage Vsgd is set to 3.5 V. Since the writing prohibition voltage Vbl is about the same as the conventional one, the junction leakage current at the bit line contact area is not different from that of the conventional case. According to the expression (1), the channel potential Vch is determined to be 7.5 V, the potential difference between the channel and the control gate is determined to be 12.5 V (where Vpgm is 20 V) to 14.5 V (where Vpgm is 22 V). Therefore, false writing does not occur as in the case where the writing voltage Vpgm is up to 19 V.

As described above, in the non-volatile semiconductor memory device according to the embodiment of the invention, the writing prohibition voltage Vbl during writing operation of “1” is decreased while the writing voltage Vpgm is low, so that the reverse bias applied to the junction at the bit contact BC section decreases, and accordingly, the junction leakage current decreases. Therefore, the power consumption of the entire chip can be reduced.

In the present embodiment, the writing prohibition voltage Vbl is stepped up in two stages. Alternatively, it may be stepped up in three or more stages.

In order to reduce the junction leakage current at the bit line contact area, the writing prohibition voltage Vbl preferably has a smaller value. However, in a case where the writing prohibition voltage Vbl is less than a voltage value (Vsgd−Vsth), the selection gate transistor S1 does not turn off, and the channel section does not attain floating state. Therefore, the voltage value (Vsgd−Vsth) is the lower limit of the writing prohibition voltage Vbl.

### Second Embodiment

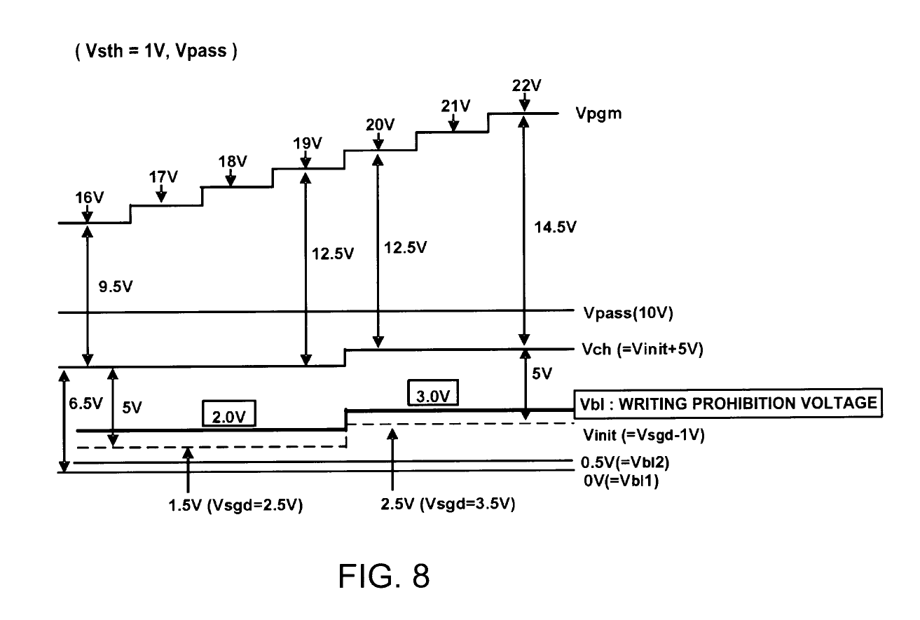

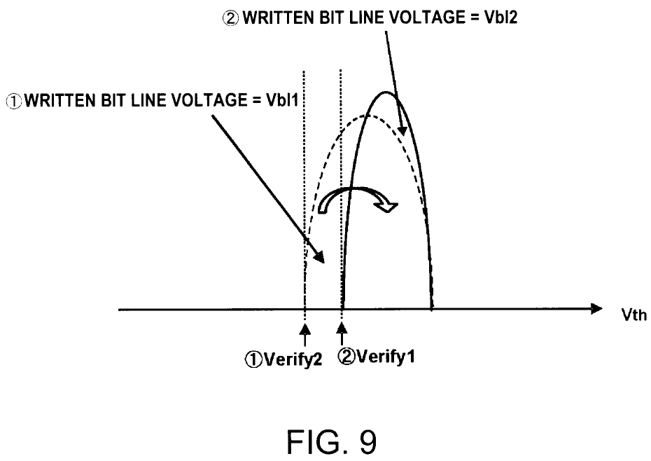

Subsequently, the non-volatile semiconductor memory device according to a second embodiment of the invention will be described with reference to FIGS. 8 and 9.

The non-volatile semiconductor memory device according to the second embodiment has the same structure as that of the first embodiment, but is different from the previous embodiment in that a verify voltage and the bit line voltage of a cell written with “0” are changed, so that after “0” is written into the memory cell transistor, the threshold voltage verification is performed twice. As shown in FIG. 9, in the first writing operation of “0” in which Vbl=Vbl1=0V holds, the verification voltage is Verify 2. As shown in FIG. 8, with regard to the memory cell into which “1” is written, when the writing voltage Vpgm is 16 V to 19 V during the first writing operation, the writing prohibition voltage Vbl (2 V) and the gate voltage Vsgd (2.5 V) are applied to the bit line and the gate of the bit line side selection transistor, respectively. At the moment, according to the expression (1), the channel potential Vch is determined to be 6.5 V, and the potential difference between the channel and the control gate is determined to be 9.5 V (where Vpgm is 16 V) to 12.5 V (where Vpgm is 19 V).

With regard to the memory cell into which “1” is written, when the writing voltage Vpgm is 20 V to 22 V, the writing prohibition voltage Vbl (3 V) and the gate voltage Vsgd (3.5 V) are applied to the bit line and the gate of the bit line side selection transistor, respectively. According to the expression (1), the channel potential Vch is determined to be 7.5 V, and the potential difference between the channel and the control gate is determined to be 12.5 V (where Vpgm is 20 V) to 14.5 V (where Vpgm is 22 V).

Subsequently, with regard to memory cell transistors whose threshold voltage is Verify 2 or more or Verify 1 or less after the first writing operation, the second writing operation of “0” is performed under the condition where the verification voltage is Verify 1 and the writing prohibition voltage is Vbl=Vbl2=0.5V. At the occasion, the gate potential Vsgd is set to be 2.0 V so that the writing prohibition voltage Vbl2 can be transferred to the channel. The writing operation of “0” under the above condition is suitable for slightly adjusting the threshold voltage of the memory cell transistor to narrow the distribution width of the threshold voltage because the channel potential increases to alleviate the electric field between the channel and the floating gate. In such a case, with regard to the memory cell to which “1” is written, the bit line voltage (writing prohibition voltage) Vbl is stepped up as shown in FIG. 8 as described above.

As described above, according to the non-volatile semiconductor memory device according to the second embodiment, the writing prohibition voltage Vbl during writing operation of “1” is decreased while the writing voltage Vpgm is low, so that the reverse bias applied to the junction at the bit contact area decreases, and accordingly, the junction leakage current decreases. Therefore, the power consumption of the entire chip can be reduced.

In the second embodiment, the writing prohibition voltage Vbl is stepped up in two stages. Alternatively, it may be stepped up in three or more stages.

The above explanation is directed to the memory cell transistor having the floating gate electrode. However, the invention can also be applied to a NAND flash memory having MONOS type memory cell transistors.

The present invention is not limited directly to the above described embodiments. In practice, the structural elements can be modified without departing from the spirit of the invention. Various inventions can be made by properly combining the structural elements disclosed in the embodiments. For example, some structural elements may be omitted from all the structural elements disclosed in the embodiments. Furthermore, structural elements in different embodiments may properly be combined. It is to therefore be understood that within the scope of the appended claims, the present invention may be practiced other than as specifically disclosed herein.

What is claimed is:

1. A non-volatile semiconductor memory device, comprising:
a semiconductor substrate;
a plurality of element regions formed on the substrate in a column direction and separated by element isolation regions arranged between adjacent element regions, respectively;
a plurality of memory cell transistors connected in series on the plurality of element regions, the respective memory cell transistors including diffusion regions, a gate insulating layer, a charge accumulation layer and a control gate;
a selection gate transistor formed on the element regions, connected to one terminal of the plurality of memory cell transistors arranged in series and having diffusion regions, a gate insulating layer and a gate;
bit lines formed extending in the column direction and connected to the diffusion regions of the selection gate transistors on the opposite side of the memory cell transistors;
word lines extending in a row direction to respectively connect adjacent control gates of the memory cell transistors;
a selection gate line arranged in parallel with the word lines to respectively connect gates of adjacent selection gate transistors; and
wherein two or more values of writing prohibition voltages are applied to the bit lines corresponding to a writing voltage of the word line, during a writing operation to write data in the memory cell transistor while the writing voltage of the word line is increased in a stepwise, and two or more values of selection gate line voltages, corresponding to the writing prohibition voltages applied to the bit lines, are applied to the gates of the selection gate transistors.

2. The non-volatile semiconductor memory device according to claim 1, wherein the writing prohibition voltages having two or more voltage values are set to a higher voltage with the stepwise increase of the writing voltage of the word line.

3. The non-volatile semiconductor memory device according to claim 1, wherein the selection gate line voltages having two or more voltage values are set to a higher voltage with the stepwise increase of the writing voltage of the word line.

4. The non-volatile semiconductor memory device according to claim 1, wherein a voltage difference between the selection gate line voltage and the writing prohibition voltage is smaller than a threshold voltage of the selection gate transistor.

5. The non-volatile semiconductor memory device according to claim 1, wherein the writing operation includes a first verify operation for a first verify voltage and a second verify operation for a second verify voltage, and two kinds of writing prohibition voltages corresponding to each of the first and second verify voltages are applied to the bit lines.

6. The non-volatile semiconductor memory device according to claim 1, wherein the memory cell is formed of MONOS transistors.

7. A non-volatile semiconductor memory device, comprising:
a memory cell configured by a plurality of memory cell transistors connected in series, and respective memory cell transistors having a charge accumulation layer and a control gate stacked on the charge accumulation layer through an insulating layer;
a first selection gate transistor connected to one terminal of the memory cell, having a gate, a source and a drain;
a bit line connected to the drain of the first selection gate transistor;
word lines connected to the control gates of the memory cell transistors, respectively; and
a selection gate line connected to the gate of the first selection gate transistor; and
wherein two or more values of writing prohibition voltages are applied to the bit line corresponding to a writing voltage of the word line, during a writing operation to write data in the memory cell transistor while the writing voltage of the word line is increased in a stepwise, and two or more values of selection gate line voltages, corresponding to the writing prohibition voltages applied to the bit line, are applied to the gate of the first selection gate transistor.

8. The non-volatile semiconductor memory device according to claim 7, further comprising, a second selection gate transistor connected to the other terminal of the memory cell.

9. The non-volatile semiconductor memory device according to claim 8, wherein the second selection gate transistor is connected to a source line.

10. The non-volatile semiconductor memory device according to claim 7, wherein the writing prohibition voltages having two or more voltage values are set to a higher voltage with the stepwise increase of the writing voltage of the word line.

11. The non-volatile semiconductor memory device according to claim 7, wherein a voltage of a non-selected word line is set lower than the writing voltage, and the selection gate line voltages having two or more voltage values are set to a higher voltage with the stepwise increase of the writing voltage of the word line.

12. The non-volatile semiconductor memory device according to claim 7, wherein voltage difference between the selection gate line voltage and the writing prohibition voltage is smaller than a threshold voltage of the selection gate transistors.

13. The non-volatile semiconductor memory device according to claim 7, wherein the writing operation includes a first verify operation for a first verify voltage and a second verify operation for a second verify voltage, and two kinds of writing prohibition voltages corresponding to each of the first and second verify voltages are applied to the bit lines.

14. The non-volatile semiconductor memory device according to claim 7, wherein the memory cell is formed of MNOS transistors.

15. A non-volatile semiconductor memory device comprising:
a plurality of NAND cells arranged in a matrix of rows and columns, each of the NAND cells having a plurality of memory cell transistors connected in series and first and second selection gate transistors connected to both terminals of the memory cell transistors, and wherein the respective memory cell transistors have a charge accumulation layer and a control gate stacked on the accumulation layer, and each of the first and second selection gate transistors has a gate, a source and a drain;
a plurality of bit lines connected to the drains of the first selection gate transistors in the NAND cells, extending in the column direction;
a plurality of word lines commonly connected to the control gates of adjacent memory cell transistors, extending in the row direction; and
first and second selection gate lines connected to the gates of the first and second selection gate transistors and arranged in parallel with the word lines; and
wherein two or more values of writing prohibition voltages are applied to the bit lines corresponding to a writing voltage of the word lines, during a writing operation to write data in the memory cell transistors while the writing voltage of the word line is increased in a stepwise, and two or more values of selection gate line voltages, corresponding to the writing prohibition voltages applied to the bit lines, are applied to the gate electrodes of the first selection gate transistors.

16. The non-volatile semiconductor memory device according to claim 15, wherein the first selection gate transistor is connected to the bit line and the second selection gate transistor is connected to a source line commonly used for the plurality of NAND cells.

17. The non-volatile semiconductor memory according to claim 15, wherein the writing operation includes a first verify operation for a first verify voltage and a second verify operation for a second verify voltage, and two kinds of writing prohibition voltages corresponding to each of the first and second verify voltages are applied to the bit lines.
